(19) United States
(12) Patent Application Publication
(10) Pub. No.: US 2007/0159872 A1
(43) Pub. Date: Jul. 12, 2007

(54) SRAM device and method for manufacturing the same

(75) Inventor: Sung Hee Park, Seoul (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/648,471

(22) Filed: Dec. 28, 2006

(30) Foreign Application Priority Data
Dec. 29, 2005 (KR) 10-2005-0134467

(51) Int. Cl. G11C 11/00

(52) U.S. Cl. 365/154

(57) ABSTRACT

An SRAM device including first and second access transistor composed of an N channel MOS transistor, first and second drive transistors composed of the N channel MOS transistor, and first and second P channel thin film transistor functioning as a pull-up device, comprises: a well formed by implanting a dopant of a conductivity an opposite to that of a semiconductor substrate in the semiconductor substrate; a first active region in which a drain of the first access transistor and a drain of the first drive transistor are formed; a second active region in which a drain of the second access transistor and a drain of the second drive transistor are formed; and a groove line for isolating the first active region and the second active region from each other, wherein the first access transistor, the first drive transistor, the first thin film transistor are formed in point-symmetrical relation with the second access transistor, the second drive transistor, and the second thin film transistor based on a center of the groove line.

### BACKGROUND OF THE INVENTION

1. Field of the Invention

The present invention relates to a static random access memory (referred to as ‘SRAM’ hereinafter) and a method for manufacturing the same.

2. Description of the Related Art

An SRAM device is a memory device capable of always storing data in a circuit using a latch manner. The SRAM device has high operation speed and low power consumption, and needs not refresh stored information unlike a dynamic random access memory (DRAM) device.

In general, the SRAM device includes two pull-down devices, two access devices, and two pull-up devices. The SRAM device is classified into a complete CMOS type, a high load resistor (HLR) type, and a thin film transistor (TFT) type. In the complete CMOS type SRAM device, a p-channel bulk MOSFET functions as a pull-up device. In the HLR type SRAM device, a poly silicon layer having high resistance value functions as a pull-up device. In the TFT type SRAM device, p-channel poly silicon thin film transistor functions as a pull-up device. Here, because the TFT type SRAM device can significantly reduce a size of the cell, it is easily applicable to a semiconductor storage device, which is used as a storage private device.

FIG. 1 is a circuitry diagram showing an SRAM according to the related art. In FIG. 1, a PMOS thin film transistor (which may also be a MOS transistor) is used as a resistor device.

With reference to FIG. 1, an SRAM cell according to the related art includes N channel access MOS transistors Ta1 and Ta2, P channel TFTs Tf1 and Tf2, and N channel drive MOS transistors Td1 and Td2. When a word line WL is activated, the N channel access MOS transistors Ta1 and Ta2 connect a bit line BL and a bit line bar /BL to a first node N1 and a second node N2 of a memory cell. The P channel TFTs Tf1 and Tf2 are coupled between a power supply Vcc and the first and second nodes N1 and N2. The N channel drive MOS transistors Td1 and Td2 are coupled between the first and second nodes N1 and N2 and a ground source Vss. Here, the P channel TFT Tf1 and the drive transistor Td1 are controlled by a signal of the second node N2, and supply a voltage of the power supply Vcc and a voltage of the ground source Vss to the first node N1. In the same manner, the P channel TFT Tf2 and the drive transistor Td2 are controlled by a signal of the first node N1, and supply a voltage of the power supply Vcc and a voltage of the ground source Vss to the second node N2.

The first node N1 is a junction point of the N channel access MOS transistor Ta1 being an access device, the N channel drive MOS transistor Td1 being a pull-down device, the P channel TFT Tf1 being a pull-up device in order to store data. Further, the second node N2 is a junction point of the N channel access MOS transistor Ta2, the N channel drive MOS transistor Td2, and the P channel TFT Tf2 in order to store data.

There are various constructions of an SRAM. A complete CMOS SRAM including 6 transistors has been widely used. Since the complete CMOS SRAM has a great area, it needs a TFT in order to improve an integration degree of a memory cell. A conventional SRAM structure to improve the integration degree is asymmetrical, it can injure the stability of the memory cell and deteriorate the yield of a memory device.

### SUMMARY OF THE INVENTION

Accordingly, the present invention is directed to an SRAM device and a method for manufacturing the same that substantially obviate one or more problems due to limitations and disadvantages of the related art.

An object of the present invention is to provide an SRAM device and a method for manufacturing the same, which may improve the yield of a device by securing the symmetry while enhancing an integration degree.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided an SRAM device including first and second access transistor composed of an N channel MOS transistor, first and second drive transistors composed of the N channel MOS transistor, and first and second P channel thin film transistor functioning as a pull-up device, comprising: a well formed by implanting a dopant of a conductivity an opposite to that of a semiconductor substrate in the semiconductor substrate; a first active region in which a drain of the first access transistor and a drain of the first drive transistor are formed; a second active region in which a drain of the second access transistor and a drain of the second drive transistor are formed; and a groove line for isolating the first active region and the second active region from each other, wherein the first access transistor, the first drive transistor, the first thin film transistor are formed in point-symmetrical relation with the second access transistor, the second drive transistor, and the second thin film transistor based on a center of the groove line.

In another aspect of the present invention, there is provided method for manufacturing an SRAM device including first and second access transistor composed of an N channel MOS transistor, first and second drive transistors composed of the N channel MOS transistor, and first and second P channel thin film transistor functioning as a pull-up device, comprising: implanting a dopant of a conductivity opposite to that of a semiconductor substrate in the semiconductor substrate to form a well; defining an active region at the semiconductor substrate; forming first and second trenches in the active region to face each other; forming gates of the first and second drive transistors, which are buried in the first and second trenches, respectively; forming gates of the first and second access transistors on the semiconductor substrate; implanting a dopant in the active region on the whole; and forming a groove line for isolating a first active region and a second active region from each other, a junction of the first access transistor and the first drive transistor is formed at the first active region, and a junction of the second access transistor and the second drive transistor is formed at the second active region.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a circuitry diagram showing an SRAM according to the related art. In FIG. 1, a PMOS thin film transistor is used as a resistor device;

FIGS. 2A, 3A, and 4A are layout views showing a construction of an SRAM device of the present invention according to a process order; and

FIGS. 2B, 3B, and 4B are cross-sectional views of the SRAM device taken along line I-I of FIGS. 2A, 3A, and 4A.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, an SRAM device and a method for manufacturing the same according to an embodiment of the present invention will be described with reference to the accompanying drawings.

In an embodiment according to the present invention, an expression of forming “on” each layer means that it is included to form directly or indirectly on it.

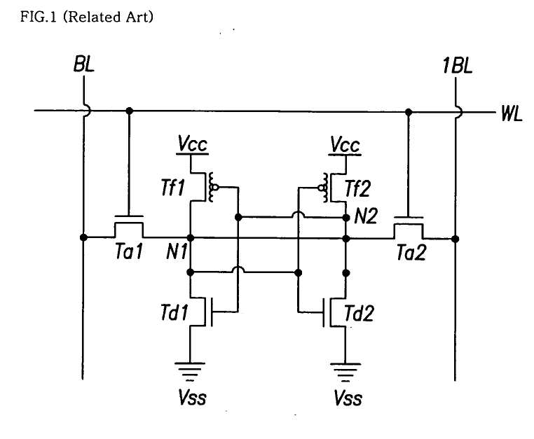

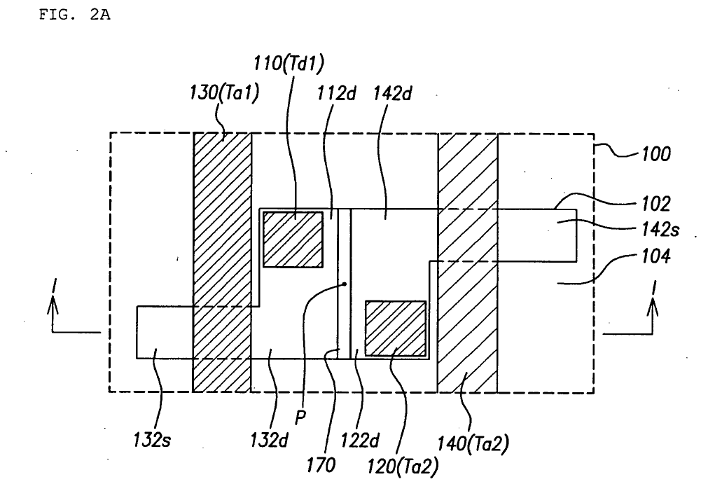

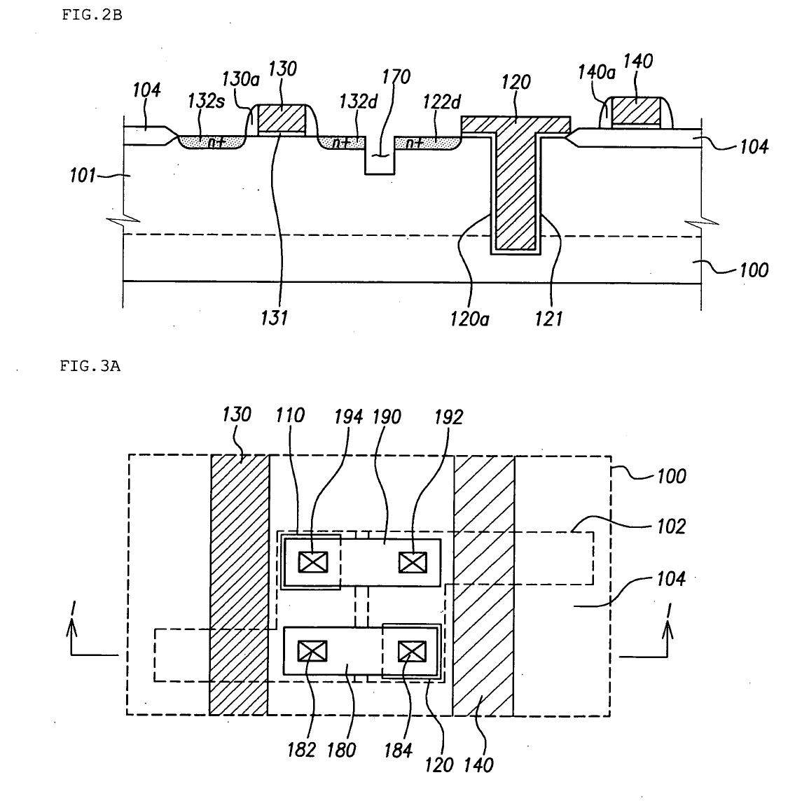

A circuitry diagram of an SRAM according to the present invention is identical with that of FIG. 1. FIGS. 2A, 3A, and 4A are layout views showing a construction of an SRAM device of the present invention according to a process order. FIGS. 2B, 3B, and 4B are cross-sectional views of the SRAM device taken along line I-I of FIGS. 2A, 3A, and 4A.

With reference to FIGS. 2A and 2B, a dopant (namely, P-type) of a conductivity opposite to that of a semiconductor substrate is implanted in an N-type semiconductor substrate 100 to form a well 101. A device isolation layer 104 is formed on the substrate 100 to define an active region 102.

Next, as shown in FIG. 2B, so as to form a second drive transistor Td2, a trench 120a is formed on a substrate. Although not shown in FIG. 2B, another trench is formed at a region in which a first drive transistor Td1 will be formed. Then, the substrate 100 is oxidized to form a gate oxide layer 121 around a trench in which the first and second drive transistors Td1 and Td2 will be formed. Further, a poly silicon layer is deposited and patterned on the substrate 100 to form a gate 110 of the first drive transistor Td1 and a gate 120 of the second drive transistor Td2.

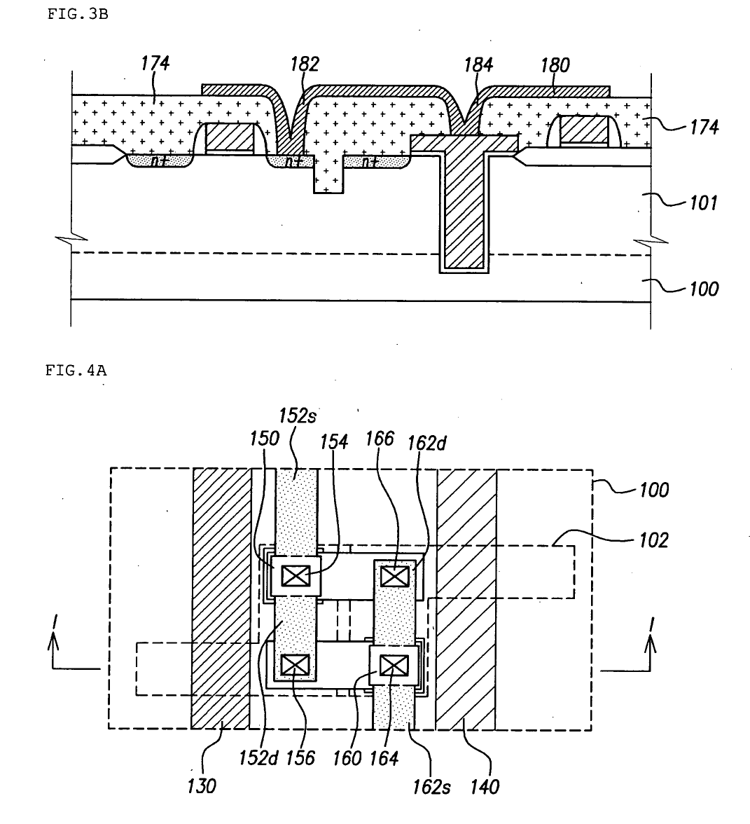

Each of the gates 110 and 120 of the first and second drive transistors Td1 and Td2 includes a vertical portion and an extension portion. The vertical portion is buried in each trench. The extension portion is arranged on the active region 102 and is approximately square. For example, the extension portion of the gate 120 has a sufficient area to form a contact 184 (FIG. 3B) during a subsequent process. The vertical portion of the gate is buried in a trench 120a, which is formed at the substrate. In particular, the trench is formed more deeply than the well 101, so that a back bias is applied to a drive transistor. Moreover, the substrate 100 is used as a ground source Vss. Accordingly, sources of the first and second drive transistors Td1 and Td2 are grounded.

After a gate of the drive transistor is formed, a gate oxide layer 131 of the first access transistor Ta1, a gate oxide layer 131, a gate 130, and spacers 130a of the first access transistor Ta1 are formed. Simultaneously, a gate oxide layer, a gate 140, and spacers 140a of the second access transistor Ta2 are formed at another side of the first access transistor Ta1.

Next, an N-type dopant is implanted in an active region 102 of a substrate to simultaneously form sources 132s and 142s, and drains 132d and 142d of the first and second access transistors Ta1 and Ta2, and drains 112d and 122d of the first and second drive transistors Td1 and Td2. At this time, the drain 112d of the first drive transistor Td1 and the drain 132d of the first access transistor Ta1 are coupled to each other. Further, the drain 122d of the second drive transistor Td2 and the drain 142d of the second access transistor Ta2 are coupled to each other.

On the other hand, in the aforementioned method, since a dopant is simultaneously implanted in one active region 102, although diffusion regions of opposite drive transistors and access transistors should be isolated from each other, they are not isolated from each other. Accordingly, a groove line 170 is formed at an active region 102 of a substrate, and is divided into a first active region and a second active region. Here, the drains 112d and 132d are formed at the first active region, and the drains 122d and 142d are formed at the second active region. At this time, the groove line 170 is preferably formed to be more deeply than a depth of an N+ diffusion region.

In the SRAM having the aforementioned construction, after one active region is firstly defined, N channels of respective MOS transistors are simultaneously formed during a subsequent process. Further, N+ junction regions of opposite drive transistors and access transistors are isolated from each other through the groove line. Moreover, respective drive transistors and access transistors are formed in point-symmetrical relation with each other based on a center P of the groove line 170.

Accordingly, the symmetry of a memory cell of an SRAM device can maintain, thereby enhancing the stability of a device. Moreover, because gates 110 and 120 of the drive transistors Td1 and Td2 are vertically formed, it occupies a minimal area on a plane of the substrate. This causes the integration degree of the cell to be improved.

Next, as shown in FIGS. 3A and 3B, an inter layer dielectric 174 is formed on the resulting object 174 shown in FIGS. 2A and 2B. Here, the groove line 170 is filled with the inter layer dielectric 174. A first node 180 and a second node 190 are formed on the inter layer dielectric 174, and are mode of a doped poly silicon layer or tungsten. The first node 180 is coupled to the drain 132d of the first access transistor Ta1 and the drain 112d of the first drive transistor Td1 through a contact 182, and the gate 120 of the second drive transistor Td2 through a contact 184.

The second node 190 is coupled to the drain 142d of the second access transistor Ta2 and the drain 122d of the second drive transistor Td2 through a contact 192, and the gate 120 of the first drive transistor Td1 through a contact 194.

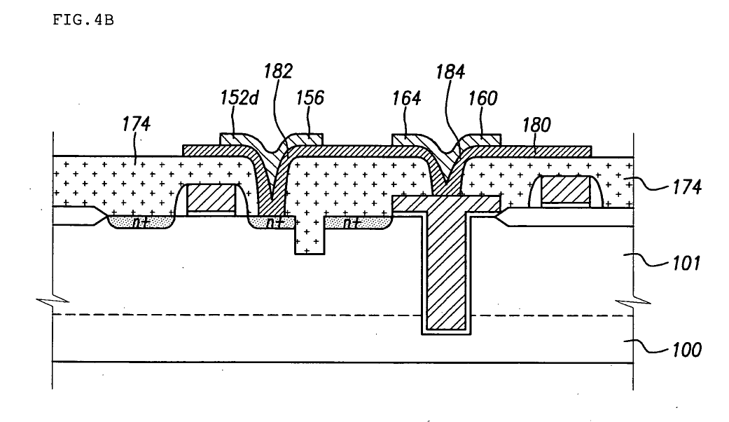

Then, as shown in FIGS. 4A and 4B, P channel thin film transistors Tf1 and Tf2 are formed on the first node 180 and the second node N2. A gate 150 of the first thin film transistor Tf1 is coupled to the second node 190 through a contact 154. Further, the first thin film transistor Tf1 includes a source 152s and a drain 152d implanted by P-type dopant with the gate 150 between. Here, the drain 152d is coupled with the first node 180 through the contact 157, and the source 152s is coupled to the power supply Vss.

In addition, the gate 160 of the second thin film transistor Tf1 is coupled with the first node 180 through a contact 164. Further, the second thin film transistor Tf2 includes a source 162s and a drain 162d implanted by P-type dopant with the gate 150 between. Here, the drain 162d is coupled with the second node 190 through the contact 166, and the source 162s is coupled to the power supply Vss.

Finally, after another inter layer dielectric is formed on a resulting object shown in FIGS. 4A and 4B, a contact is formed at the another inter layer dielectric to couple the source 132s of the first access transistor Ta1 and the source 142s of the second access transistor Ta2 to the bit line BL and the bit line bar /BL, with the result that a series of an SRAM device is completed.

As is clear from the forgoing description, in the SRAM device and the method for manufacturing the same, after one region is first defined, N channels of respective MOS transistors are simultaneously formed, and junction regions of opposite driver transistors and access transistors are isolated from each other through a groove line. In the event, the present invention has a simpler process in comparison with a process for manufacturing an SRAM according to the related art defining at least two active regions.

Moreover, in the present invention, respective drive transistors and access transistors are formed point-symmetrical relation with each other. Accordingly, the memory cell of the SRAM may maintain the symmetry to improve the reliability of a device.

In addition, in the present invention, since gates 110 and 120 of the drive transistors Td1 and Td2 are vertically formed, it occupies a minimal area on the plane of the substrate. This causes the integration degree of the cell to be enhanced.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. An SRAM device including first and second NMOS access transistors, first and second NMOS drive transistors, and first and second P channel transistors functioning as pull-up devices, comprising:
a well in a semiconductor substrate, the well having a conductivity opposite to that of the semiconductor substrate;
a first active region containing a drain of the first access transistor and a drain of the first drive transistor;
a second active region containing a drain of the second access transistor and a drain of the second drive transistor; and
a groove line configured to isolate the first active region and the second active region from each other,
wherein the first access transistor, the first drive transistor, the first P channel transistor are in point-symmetrical relation with the second access transistor, the second drive transistor, and the second P channel transistor based on a center of the groove line.

2. The SRAM device according to claim 1, wherein the well comprises a dopant implant region in the substrate.

3. The SRAM device according to claim 1, wherein the groove line has a depth greater than the drains in the first and second active regions.

4. The SRAM device according to claim 3, wherein the groove line comprises a dielectric.

5. The SRAM device according to claim 1, wherein a gate of the first drive transistor includes an extension on the first active region, and a vertical portion in a first trench, in contact with the extension.

6. The SRAM device according to claim 1, wherein the first trench is in the first active region.

7. The SRAM device according to claim 5, wherein a gate of the second drive transistor includes an extension on the second active region, and a vertical portion in a second trench, in contact with the extension.

8. The SRAM device according to claim 7, wherein the second trench is in the second active region.

9. The SRAM device according to claim 7, wherein the first trench or the second trench has a depth greater than the well.

10. The SRAM device according to claim 7, wherein the first trench and the second trench have a depth greater than the well.

11. A method for manufacturing an SRAM device including first and second NMOS access transistors, first and second NMOS drive transistors, and first and second P channel transistors functioning as pull-up devices, comprising:
implanting a first dopant in a semiconductor substrate to form a well, the first dopant having a conductivity opposite to that of the semiconductor substrate;
forming first and second trenches in an active region;
forming gates of the first and second drive transistors in the first and second trenches;
forming gates of the first and second access transistors on the semiconductor substrate;
implanting a second dopant in the active region; and
forming a groove line to isolate a first active region from a second active region, wherein a junction of the first access transistor and a junction of the first drive transistor are in the first active region, and a junction of the second access transistor and a junction of the second drive transistor are in the second active region.

12. The method according to claim 11, wherein the first and second trenches are formed in the well.

13. The method according to claim 11, further comprising forming a dielectric layer on the substrate including the first and second access transistors and the first and second drive transistors; and
forming a first node coupled to the junction of the first access transistor, the junction of the first drive transistor, and the gate of the second drive transistor, and a second node coupled to the junction of the second access transistor, the junction of the second drive transistor, and the gate of the first drive transistor.

14. The method according to claim 13, further comprising forming first and second transistors intersecting each other on the first and second nodes.

15. The method according to claim 11, wherein the groove line has a depth greater than the junctions of the first access transistor, the first drive transistor, the second access transistor, and the second drive transistor.

16. The method according to claim 11, wherein the first and second trenches have a depth greater than the well.

17. The method according to claim 11, wherein implanting the second dopant forms the junctions of the first access transistor, the first drive transistor, the second access transistor, and the second drive transistor.
